(19) United States
(12) Patent Application Publication
(10) Pub. No.: US 2002/0130404 A1
(43) Pub. Date: Sep. 19, 2002

(54) Semiconductor module in which plural semiconductor chips are enclosed in one package

(76) Inventors: Toshihiro Ushijima, Yokohama-shi (JP); Isao Ozawa, Chigasaki-shi (JP)

Correspondence Address: HOGAN & HARTSON L.L.P., 500 S. GRAND AVENUE, SUITE 1900, LOS ANGELES, CA, 90071-2611, US

(21) Appl. No.: 10/102,599

(22) Filed: Mar. 18, 2002

(30) Foreign Application Priority Data
Mar. 19, 2001 (JP) 2001-079194

(51) Int. Cl. H01L 23/02

(52) U.S. Cl. 257/686

(57) ABSTRACT

A semiconductor module includes first and second semiconductor chips having first and second element surfaces where first and second electrode pads are provided. The first semiconductor chip is provided on a second main surface of a substrate with the first element surface facing the substrate. The second semiconductor chip is provided on the first semiconductor chip with a surface opposite to the second element surface facing a surface opposite to the first element surface. First and second wiring patterns are provided on the first and second main surfaces and connected to each other. The first and second wiring patterns have first and second connection parts. First and second connection wire connect the first and second electrode pads to the first and second connection parts respectively. An external terminal is provided on the first wiring pattern. A sealing member covers the second connection wire.

### CROSS-REFERENCE TO RELATED APPLICATIONS

This application is based upon and claims the benefit of priority from the prior Japanese Patent Application No. 2001-079194, filed Mar. 19, 2001, the entire contents of which are incorporated herein by reference.

### BACKGROUND OF THE INVENTION

1. Field of the Invention

The present invention relates to a package structure of a semiconductor module and particularly to a package structure of a semiconductor product in which plural semiconductor chips are enclosed in one package.

2. Description of the Related Art

Developments have been made in a semiconductor module of a so-called CSP (Chip Scale Package) in which a chip having a size substantially equal to a substrate is provided on the substrate. In the CSP, a method using a TAB (Tape Automated Bonding) tape, flip-chip bonding, or the like has been known as a means for connecting a semiconductor chip such as a SRAM, flash EEPROM, FeRAM, DRAM, or the like to a circuit substrate or the like.

FIG. 9 is a cross-sectional view schematically showing a semiconductor module using a conventional TAB tape. In FIG. 9, the reference numeral 31 denotes a TAB tape. The TAB tape 31 has a base member 32. A wiring pattern 33 is provided on the base member 32 with an adhesive (not shown) interposed therebetween. The wiring pattern 33 is formed, for example, by etching copper foil on the base member 32. On the surface of the TAB tape 31, which is opposite to the wiring pattern 33, a semiconductor chip 36 having a thickness of, for example, 180 μm is provided with an adhesive 35 interposed therebetween. The semiconductor chip 36 is arranged, so-called, facing down such that the surface where an electrode pads (hereinafter called an active element surface) are provided is set downsides. The reference numerals 37 and 38 respectively denote an electrode pad and a solder resist. The reference numeral 39 denotes a wire made of gold, for example, and connects the electrode pad 37 to a connection part 33a of the wiring pattern 33. The reference numeral 40 denotes a protection member which is provided to protect the connection part 33a and the wire 39.

The semiconductor module described above is constructed in a structure using only one semiconductor chip. Therefore, for example, a semiconductor chip comprised of a logic circuit such as a CPU or the like and a semiconductor chip comprised of peripheral circuits thereof cannot be provided in one same module as one system. In conventional cases of systemization, for example, plural semiconductor modules and the like are provided on a circuit substrate, and the semiconductor modules are connected to each other by wires. Therefore, the lengths of the wires are elongated and cause difficulties in attaining high-speed processing.

Also, in a semiconductor module including one semiconductor chip, for example, it is difficult to increase the memory capacity and to systemize the module without changing the module size. That is, to upgrade the capacity or system, the size of the module must be enlarged. Hence, in association with upgrading of the memory capacity or the like, efficiency of installation on a circuit substrate is lowered in all points of the occupation area, occupation volume, and weight of the module.

In addition, in the semiconductor module constructed as described above, the semiconductor chip is naked. Therefore, the semiconductor chip is easily influenced from the outside, and it is difficult to avoid damages such as scratching, partial chipping, cracking, and the like.

In accordance with recent conspicuous technical developments, drastic downsizing and weight reduction of semiconductor chips have achieved. As a result, recently, the thickness of semiconductor chips have become about 60 μm from 180 μm, and thus, thinning has been realized. However, only one semiconductor chip of this kind can conventionally be installed on a module. Further, due to the same reason as described above, system upgrading is not easy. A problem remains in that the wiring distance is elongated when a plurality of modules are installed on a substrate, so that high-speed processing is difficult.

### BRIEF SUMMARY OF THE INVENTION

According to a first aspect of the present invention, there is provided a semiconductor module comprising: a first semiconductor chip having a first element surface where a first electrode pad is provided; a second semiconductor chip having a second element surface where a second electrode pad is provided, the second semiconductor chip being arranged on the first semiconductor chip such that a surface opposite to the second element surface faces a surface opposite to the first element surface; a circuit substrate having first and second main surfaces opposite to each other, the first semiconductor chip being provided on the second main surface such that the second main surface faces the first element surface and that the circuit substrate has a first extending part extending from the first semiconductor chip in a plane, the circuit substrate further including an opening part corresponding to the first electrode pad, a first wiring pattern provided on the first main surface and having a first connection part provided near the opening part, and a second wiring pattern provided on the second main surface and having a second connection part provided on the first extending part, the first and second wiring patterns being connected electrically; a first connection wire electrically connecting the first electrode pad to the first connection part; a second connection wire electrically connecting the second electrode pad to the second connection part; an external connection terminal provided on the first wiring pattern; and a first insulative sealing member covering the second connection wire.

### BRIEF DESCRIPTION OF THE SEVERAL VIEWS OF THE DRAWING

FIG. 1 is a cross-sectional view showing a semiconductor module according to the first embodiment of the present invention;

FIGS. 2A and 2B are plan views showing pad layout of semiconductor chips;

FIG. 3 is a cross-sectional view showing a semiconductor module according to the second embodiment of the present invention;

FIG. 4 is a cross-sectional view showing a semiconductor module according to the third embodiment of the present invention;

FIG. 5 is a cross-sectional view showing a semiconductor module according to the fourth embodiment of the present invention;

FIG. 6 is a cross-sectional view showing a semiconductor module according to the fifth embodiment of the present invention;

FIG. 7 is a cross-sectional view showing a semiconductor module according to the sixth embodiment of the present invention;

FIGS. 8A, 8B, and 8C are plan views showing pad layout of semiconductor chips; and

FIG. 9 is a cross-sectional view showing a conventional semiconductor module.

### DETAILED DESCRIPTION OF THE INVENTION

Hereinafter, embodiments of the present invention will be explained with reference to the drawings. In the following explanation, structural elements having equal function and structure are denoted at one same reference symbol, and reiterative explanation thereof will be made only when required.

(First Embodiment)

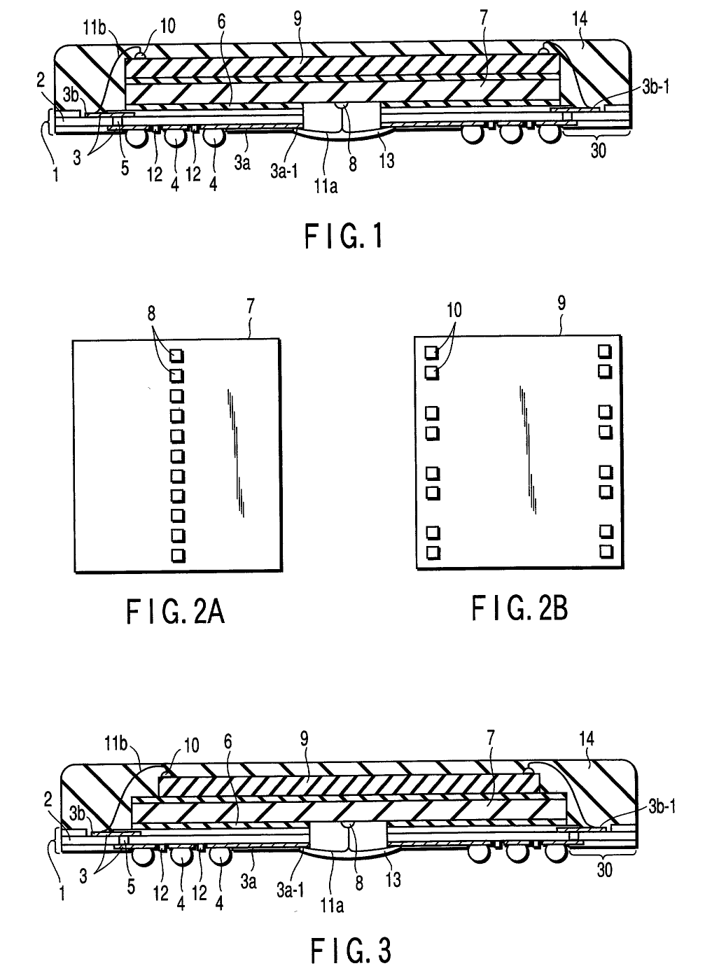

FIG. 1 is a cross-sectional view showing a semiconductor module according to the first embodiment of the present invention. In FIG. 1, the reference numeral 1 denotes a TAB tape as a substrate (circuit substrate). The substrate 1 has an opening part 31 at the substantial center of itself, which communicates its upper and lower surfaces to each other. The substrate 1 has a wiring pattern 3 made of, for example, copper. The wiring pattern 3 is formed, for example, on both surfaces of a base member 2. As a material for the base member 2, for example, a polyimide tape is used. The wiring pattern 3 has a first wiring pattern 3a formed on the upper surface of the base member 2 and a second wiring pattern 3b formed on the lower surface thereof. The first wiring pattern 3a has a connection part 3a-1 near the opening part 31. The connection part 3a-1 functions as an inner connection terminal in the semiconductor module and is connected to an electrode pad of a semiconductor chip which will be described later.

On the wiring pattern 3a, a plurality of external connection terminals 4 are provided. The external connection terminals 4 are constructed by solder balls, for example, and are provided on the wiring pattern 3. Through these external connection terminals 4, the semiconductor module is electrically connected to an external circuit not shown and the like. By the first wiring pattern 3a, the connection part 3a-1 and the external connection terminals 4 are electrically connected to each other. The wiring pattern 3 has a function to prevent the external connection terminals 4 from being peeled from the wiring pattern 3 due to thermal expansion and the like during a thermal treatment. The reference numeral 5 denotes a through hole by which the first and second wiring patterns 3a and 3b provided on both of the base member 2 are connected to each other.

For example, a semiconductor chip (first semiconductor chip) 7 having a thickness of 60 μm is provided on the TAB tape 1 with an adhesion 6 or the like interposed therebetween. The semiconductor chip 7 has a shape which is, for example, similar to the TAB tape 1, and an area smaller than the area of the TAB tape 1. In other words, a TAB tape 1 which is larger than the semiconductor chip 7 is used. The TAB tape 1 has a part 30 extending from the semiconductor chip in a plane. The wiring pattern 3b has a connection part 3b-1 on the extending part 30. The connection part 3b-1 functions as an inner connection terminal in the semiconductor module and is connected to an electrode pad of the semiconductor chip, which will be described later.

The semiconductor chip 7, as shown in FIG. 2A, is subjected to center-pad layout in which electrode pads 8 are arranged in its center. On this semiconductor chip 7, a semiconductor chip 7 (second semiconductor chip) 9 having a size equal to, for example, the semiconductor chip 7 through an adhesive 6, with its active element surface oriented upwards (this orientation will be hereinafter called face-up). For example, the semiconductor chip 7 is a logic circuit such as a CPU or the like, and the semiconductor chip 9 is a peripheral circuit. The semiconductor chips are not limited hitherto but plural memory chips can be stacked. The semiconductor chip 9 has electrode pads 10 formed on the upper surface thereof. The electrode pads 10 are formed on a peripheral part of the semiconductor chip 9, as shown in FIG. 2B. Note that the adhesive 9 can be provided in a method of applying it on the front or back surface of the chip, a method of using an adhesive sheet, or the like. In place of the adhesive, resins can be used.

The bonding wire 11a electrically connects the electrode pad 8 to the connection part 3a-1 of the first wiring pattern 3a. The bonding wire 11b electrically connects the electrode pad 10 to the connection part 3b-1 of the second wiring pattern 3b. The bonding wires 11a and 11b are made of, for example, gold. A solder resist 12 is provided so as to cover the entire surface of the TAB tape 1 except for the part where the wire 11a and the external connection terminal 4 are provided. In this manner, the part covered by the solder resist 12 is insulated from the other parts, so influence from the atmospheric air can be shut off. An inner protection member 13 protects the connection part 3a-1 of the first wiring pattern 3a and the wire 11a, and is made of, for example, mold resin or the like.

The mold resin 14 covers the entire surfaces of the TAB tape 1 and semiconductor chips 7 and 9, and so can shut off influences such as collision, contact, and the like on the semiconductor chips from the outside.

In the first embodiment, the semiconductor chip 7 is arranged on a TAB tape 1 to which wiring patterns 3 on both surfaces are electrically connected through a through hole 5, by the face-down manner. The semiconductor chip 9 is stacked on the semiconductor chip 7 by the face-up manner. They are constructed into one semiconductor module. It is therefore possible to obtain a chip area which is twice larger than the TAB tape having an area equal to that of a conventional chip. The efficiency of installation on an actual installation substrate can be greatly improved.

In addition, since a semiconductor chip having a smaller thickness than a conventional chip is used, the volume and weight of the module can be restricted to be lower even if two semiconductor chips are provided in one semiconductor module.

Also, of two semiconductor chips 7 and 9 thus provided and stacked, the semiconductor chip 9 in the upper side is arranged in peripheral-pad layout, and the semiconductor chip 7 in the lower side is arranged in center-pad layout. The electrode pads 8 and 10 and the wiring pattern 3 are electrically connected through wires 11a and 11b. Therefore, the wiring lengths can be shorter, compared with the case where modules each constructed by one semiconductor chip are disposed on an circuit substrate and the modules are connected to each other by wires or the like as well as the modules and the wiring patterns. Accordingly, the processing speed of the modules can be increased.

In addition, the layout of the electrode pads 10 of the second semiconductor chip 9 is not limited to the embodiment described above. That is, for example, it is important to arrange the connection part 3b-1 and the electrode pad 10 so as to shorten the distance between the connection part 3b-1 of the second wiring pattern 3b and the electrode pad 10 of the semiconductor chip 9. Thus, by minimizing this distance, the length of the wire 11b can be shortened which can bring much higher operation speed of the module.

(Second Embodiment)

FIG. 3 is a cross-sectional view showing a semiconductor module according to the second embodiment of the present invention. The first embodiment shows a case of using semiconductor chips 7 and 9 having one same size. In contrast, the second embodiment shows a case where the size of the upper semiconductor chip 9 is smaller than that of the lower semiconductor chip 7. The other parts are the same as those of the first embodiment.

According to the second embodiment, the same advantages as those of the first embodiment can be obtained. In addition, the module can be manufactured in the same manner as that of the first embodiment when two semiconductor chips are stacked.

(Third Embodiment)

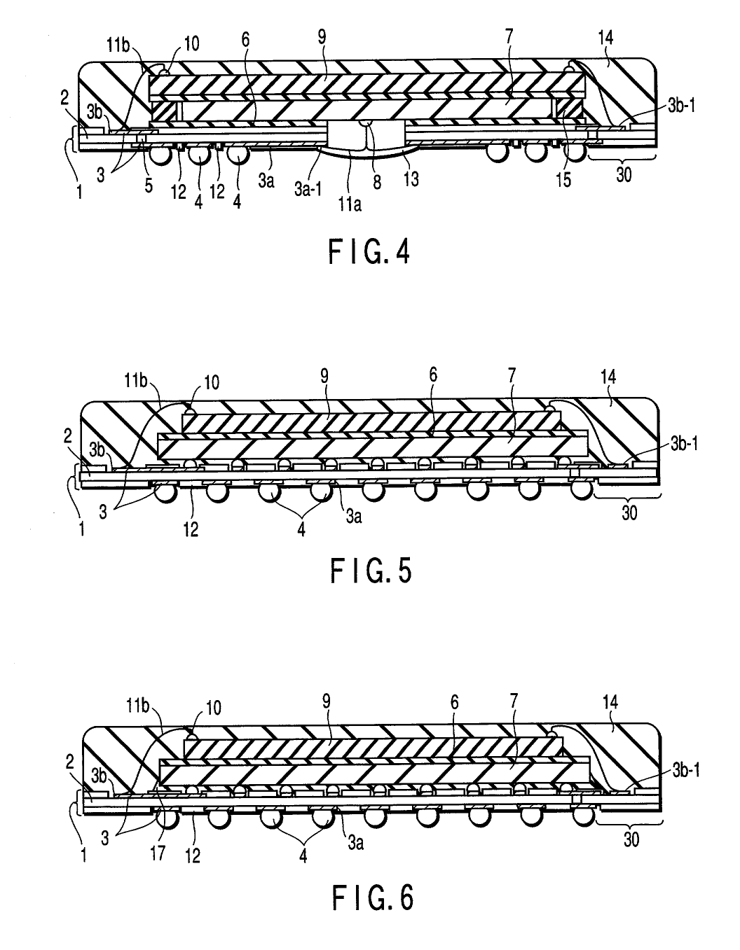

FIG. 4 is a cross-sectional view showing a semiconductor module according to the third embodiment of the present invention. The second embodiment shows a case where the size of the upper semiconductor chip 9 is smaller than that of the lower semiconductor chip 7. In contrast, the third embodiment shows a case where the size of the lower semiconductor chip 7 is smaller than that of the upper semiconductor chip 9.

In FIG. 4, the peripheral part or both end parts of the semiconductor chip 9 extend over the peripheral part or both end parts of the semiconductor chip 7. A support material 15 is inserted between the extending parts and the TAB tape 1. As the support material 15, for example, epoxy-based resin, glass epoxy, metal, or the like is used. The support material 15 can prevents the position of the semiconductor chip 9 from shifting at the time when the chip 9 is stacked. Otherwise, if the support material is not provided but the structure is hollow, the chip is unstable so that a sufficient pressure cannot be obtained at the time of bonding the wire 11b. Further, when a pressure is applied to the chip 9 due to bonding, there is a possibility that the chip 9 is deformed, damaged, or so. Hence, by providing a support material 15, the wire 11b can be provided more securely, and damages on the chip 9 can be avoided.

According to the third embodiment, the same advantages as those of the first embodiment can be obtained. In addition, the support material 15 supports the peripheral part of the semiconductor chip 9, so that positional shifts and the like can be prevented from occurring when the semiconductor chip 9 is stacked. At the same time, the chip can be prevented from damages at the time of bonding wires, and a sufficient pressure can be obtained.

Also, by providing the support material 15, the semiconductor chips can be stacked even if the size of the lower semiconductor chip 7 is smaller than that of the upper semiconductor chip 9. Therefore, two semiconductor chips can be stacked in any combination, without considering the difference in size between the chips, according to the first to third embodiments.

In the third embodiment described above, the above third embodiment has been explained with respect to the case where a great difference in size exists between the semiconductor chips 7 and 9. However, if no great difference in size exists between the semiconductor chips 7 and 9, it is possible to adopt a structure with no support material 15.

(Fourth Embodiment)

FIG. 5 is a cross-sectional view showing a semiconductor module according to the fourth embodiment of the present invention. In the first to third embodiments described above, the electrode pad 8 of the lower semiconductor chip 7 is connected to the first wiring pattern 3a through a wire 11a. However, in this method, further thinning of the module and further reduction of its weight are difficult. Hence, in the fourth embodiment, the lower semiconductor chip 7 is arranged on a TAB tape by flip-chip bonding. That is, the semiconductor chip 7 is provided with bumps 16, and wiring pattern 3 are formed on the surface of the TAB tape 1, in correspondence with the bumps. In this structure, the semiconductor chip 7 is arranged on the TAB tape 1 in the face-down manner through bumps 16. Through the bumps 16, the semiconductor chip 7 and the wiring pattern 3 are electrically connected to each other. Thereafter, a semiconductor chip 9 according to peripheral-pad layout is arranged on the semiconductor chip 7 through an adhesive 6, in the face-up manner.

According to the fourth embodiment, the lower semiconductor chip 7 is provided on the TAB tape 1 by flip-chip bonding. As a result, the thickness and weight of the module can further be reduced, compared with the case of internal connection using the wire 11a as shown in the first to third embodiments. Further, as shown in the first to third embodiments, an opening part for connection to the electrode pad 8 need not be provided in the TAB tape 1, so that the strength of the TAB tape 1 can be increased and the reliability of the semiconductor module can be improved.

FIG. 5 shows the case where the size of the upper semiconductor chip 9 is smaller than the lower semiconductor chip 7. However, the present embodiment is not limited hitherto but combinations as shown in the second and third embodiments can be practiced.

(Fifth Embodiment)

FIG. 6 is a cross-sectional view showing a semiconductor module according to the fifth embodiment of the present invention. The fifth embodiment is a modification of the fourth embodiment.

In FIG. 6, when a semiconductor chip 7 is provided on the TAB tape 1 by flip-chip bonding, an under-filler 17 made of, for example, insulative epoxy-based resin as shown in FIG. 6 is provided on the entire surface of the TAB tape 1, and thereafter, the semiconductor chip 9 is provided in a manner similar to that of the fourth embodiment. The bumps 16 of the semiconductor chip 7 are brought into contact with the wiring pattern 3, pushing away the under-filler 17. Thereafter, the bumps 16 are melted and connected to the wiring pattern 3. Subsequent process is arranged to be the same as shown in the first to fourth embodiments.

According to the fifth embodiment, it is possible to obtain the same advantages as those of the fourth embodiment. In addition, by providing the under-filler 17 between the TAB tape 1 and the semiconductor chip 7, the wiring patterns 3 can be insulated more securely from each other, as well as the bumps 16.

(Sixth Embodiment)

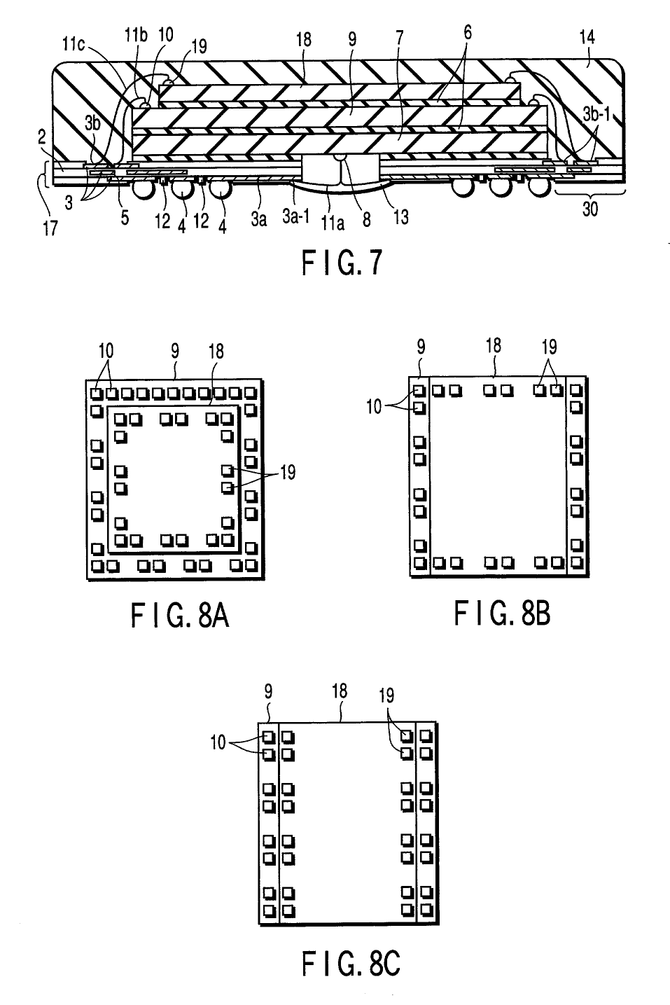

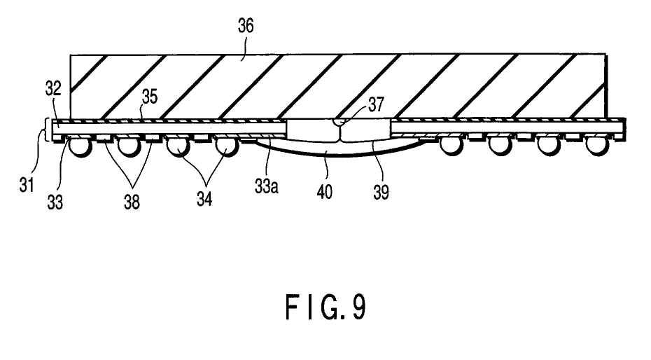

FIG. 7 is a cross-sectional view showing a semiconductor module according to the sixth embodiment of the present invention. The first to fifth embodiments have been explained with respect to the case where two semiconductor chips are stacked and the case where the wiring pattern 3 is provided on one or each of two surfaces. In contrast, in the sixth embodiment, a plurality of semiconductor chips are stacked, and a multi-layered wiring pattern is used for the substrate.

The reference 17 in FIG. 7 denotes a multi-layered-circuit substrate in which respective layers of the wiring pattern 3 are connected to each other through a through-hole 5. On this substrate 17, a semiconductor chip 7 according to the center-pad layout is provided in the face-down manner. On the semiconductor chip 7, the semiconductor chip 9 according to the peripheral-pad layout is provided in the face-up manner. On the semiconductor chip 9, a smaller semiconductor chip (third semiconductor chip) 18 according to the peripheral-pad layout than the semiconductor chip 9 is provided in a face-up manner. The semiconductor chips 7, 9, and 18 are adhered to each other, for example, by an adhesive 6. Electrode pads 8, 10, and 19 of the semiconductor chips 7, 9, and 18 are connected to the wiring pattern 3 by the wires 11a, 11b, and 11c, respectively.

The electrode pads of the semiconductor chips 9 and 18 may respectively be arranged in the peripheries of the semiconductor chips, as shown in FIGS. 8A to 8C, or arranged in combinations in which the pads are arranged at edges different from each other or at one same edge.

According to the sixth embodiment, a plurality of semiconductor chips are provided on the substrate 17 of a multi-layered-wiring pattern. Therefore, a larger chip area by one layer can be obtained so that the efficiency in installation on the circuit substrate can be improved greatly.

In addition, the semiconductor chip 7 according to the center-pad layout is set facing down, while the semiconductor chips 9 and 18 according to the peripheral-pad layout are set facing up. The electrode pads and the wiring patterns 3 are connected by wires. Therefore, in case of using a plurality of semiconductor chips, the wiring length can be shortened. Accordingly, the processing speed of the module can be improved to be higher.

In the sixth embodiment, the semiconductor chip 7 is set facing down, and the electrode pad 8 and the first wiring pattern 3a are connected by the wire 11a. However, the present invention is not limited to this but the structure may use flip-chip bonding as shown in the fourth and fifth embodiments, for example.

In each of the above embodiments, a TAB tape 1 based on a polyimide tape is used as a substrate on which semiconductor chips are provided. However, the present invention is not limited to this but a substrate made of glass epoxy resin or the like may be used, for example. Further, wiring patterns 3 may be formed on two surfaces of the base member 2 or one wiring pattern 3 may be multi-layered as shown in the sixth embodiment.

In addition, in the first to sixth embodiments, the semiconductor chip 7 can be, for example, a logic which has a low processing speed and a high access frequency, and the semiconductor chips 9 and 18 can be memories. Then, the wiring lengths of the electrode pads 8 of the semiconductor chip 7 and the wiring pattern 3 are shorter than those of the semiconductor chip 9, so that high-speed processing of the semiconductor chip 7 can be achieved and the processing speed of the module can be improved.

Additional advantages and modifications will readily occur to those skilled in the art. Therefore, the invention in its broader aspects is not limited to the specific details and representative embodiment shown and described herein. Accordingly, various modifications may be made without departing from the spirit or scope of the general inventive concept as defined by the appended claims and their equivalents.

What is claimed is:

1. A semiconductor module comprising:
a first semiconductor chip having a first element surface where a first electrode pad is provided;
a second semiconductor chip having a second element surface where a second electrode pad is provided, the second semiconductor chip being arranged on the first semiconductor chip such that a surface opposite to the second element surface faces a surface opposite to the first element surface;
a circuit substrate having first and second main surfaces opposite to each other, the first semiconductor chip being provided on the second main surface such that the second main surface faces the first element surface and that the circuit substrate has a first extending part extending from the first semiconductor chip in a plane, the circuit substrate further including an opening part corresponding to the first electrode pad, a first wiring pattern provided on the first main surface and having a first connection part provided near the opening part, and a second wiring pattern provided on the second main surface and having a second connection part provided on the first extending part, the first and second wiring patterns being connected electrically;
a first connection wire electrically connecting the first electrode pad to the first connection part;
a second connection wire electrically connecting the second electrode pad to the second connection part;
an external connection terminal provided on the first wiring pattern; and
a first insulative sealing member covering the second connection wire.

2. A semiconductor module according to claim 1, wherein the second electrode pad is provided at a peripheral part of the second semiconductor chip.

3. A semiconductor module according to claim 1, wherein
the circuit substrate has a first edge,
the second semiconductor chip has a second edge in the same direction as the first edge in a plane of the circuit substrate,
the second connection part is positioned close to the first edge, and
the second electrode pad is positioned close to the second edge.

4. A semiconductor module according to claim 1, wherein the second electrode pad and the second wiring pattern are each provided such that the second connection wire has a minimum length.

5. A semiconductor module according to claim 1, further comprising a second insulative sealing member filling the opening part.

6. A semiconductor module according to claim 1, wherein the second semiconductor chip has a second extending part extending from the edge of the first semiconductor chip, and further has a support material provided between the second extending part and the circuit substrate.

7. A semiconductor module according to claim 1, further comprising:
a third semiconductor chip having a third element surface where a third electrode pad is provided, and provided on the second semiconductor chip such that a surface opposite to the third element surface faces the second element surface and that the second electrode pad is exposed; and
a third connection wire electrically connecting the third electrode pad to the second connection part.

8. A semiconductor module comprising:
a first semiconductor chip having a first element surface where a first electrode pad is provided;
a second semiconductor chip having a second element surface where a second electrode pad is provided, the second semiconductor chip being arranged on the first semiconductor chip such that a surface opposite to the second element surface faces a surface opposite to the first element surface;
a circuit substrate having first and second main surfaces opposite to each other, the first semiconductor chip being provided on the second main surface such that the second main surface faces the first element surface and that the circuit substrate has a first extending part extending from the first semiconductor chip in a plane, the circuit substrate further including a first wiring pattern provided on the first main surface, and a second wiring pattern provided on the second main surface and having a second connection part provided on the first extending part and touching the first electrode pad, the first and second wiring patterns connected electrically;
a second connection wire electrically connecting the second electrode pad to the second connection part;
an external connection terminal provided on the first wiring pattern; and
a first insulative sealing member covering the second connection wire.

9. A semiconductor module according to claim 8, wherein the second electrode pad is provided at a peripheral part of the second semiconductor chip.

10. A semiconductor module according to claim 8, wherein
the circuit substrate has a first edge,
the second semiconductor chip has a second edge in the same direction as the first edge in a plane of the circuit substrate,
the second connection part is positioned close to the first edge, and
the second electrode pad is positioned close to the second edge.

11. A semiconductor module according to claim 8, wherein the second electrode pad and the second wiring pattern are each provided such that the second connection wire has a minimum length.
